(19) United States
(12) Patent Application Publication
(10) Pub. No.: US 2009/0107714 A1
(43) Pub. Date: Apr. 30, 2009

(54) ELECTRONIC COMPONENT MODULE AND CIRCUIT BOARD THEREOF

(75) Inventor: Koji Ogasawara, Yokohama (JP)

Correspondence Address: ARENT FOX LLP, 1050 CONNECTICUT AVENUE, N.W., SUITE 400, WASHINGTON, DC, 20036, US

(73) Assignee: FUJITSU MEDIA DEVICES LIMITED, Yokohama-shi (JP)

(21) Appl. No.: 12/259,869

(22) Filed: Oct. 28, 2008

(30) Foreign Application Priority Data
Oct. 31, 2007 (JP) 2007-284330

(51) Int. Cl. H05K 1/16

(52) U.S. Cl. 174/260

(57) ABSTRACT

An electronic component module, including: a circuit board having: an insulating layer; a plurality of conductive layers formed on respective surfaces of the insulating layer; a ground plane comprising one of the conductive layers and covering the greater part of the surface; and wiring formed on another of the surfaces and comprising the conductive layer; and an electronic component mounted on the circuit board and connected by the wiring, wherein a plurality of slits, formed by removing the conductive layer, are provided in the ground plane.

### CROSS-REFERENCE TO RELATED APPLICATIONS

This application is based upon and claims the benefit of priority of the prior Japanese Patent Application No. 2007-284330, filed on Oct. 31, 2007, the entire contents of which are incorporated herein by reference.

### BACKGROUND OF THE INVENTION

1. Field of the Invention

The present invention relates to an electronic component module, and a circuit board thereof, the electronic component module comprising an electronic component and a circuit board on which the electronic component is mounted. More particularly, the present invention relates to an electronic component module, and a circuit board thereof, the electronic component module comprising a thin circuit board that does not warp or twist even after a reflow soldering process.

2. Description of the Related Art

Recent years have witnessed a remarkable miniaturization of electronic component modules that are mounted on the motherboards of electronic devices such as cellular phones and the like. As a result, the circuit boards (so-called printed circuit boards) on which the electronic component modules are formed have become ever thinner.

Reflow soldering techniques are used for mounting electronic components on such circuit boards. In reflow soldering, cream solder is printed firstly onto the portions of the circuit board on which the electronic component is to be mounted. The electronic component is then temporarily fixed on the cream solder. In this state, the entire circuit board is heated at a temperature at or above the melting point of the solder cream, to solder thereby the electronic component to the circuit board.

The circuit board comprises, for instance, an insulating layer of glass epoxy resin, and wiring comprising a metal thin film (conductive layer) of, for instance, copper foil, formed on the surface of the insulating layer.

Circuit boards having the above build-up have become remarkably thinner in recent years, down to a thickness of 1 mm or less (for instance, 400 μm). When such circuit boards are reflow-soldered, however, the circuit board may warp and/or twist during cooling after heating.

Methods for preventing such warpage and twist include, for instance, suitably leaving multiple small metal thin films, shaped as circles or right triangles, at portions other than wiring, during formation of wiring on the insulating layer by etching of a metal thin film. In such a method, the overall surface area of the metal thin film, including the metal thin film remaining at portions other than wiring, is constant across a plurality of wiring layers (Japanese Patent Application Laid-open No. 2004-200265). The ratio of the overall surface area of the metal thin film relative to the surface area of the insulating layer is referred to hereafter as the residual ratio.

FIG. 1 is a diagram for explaining the surface of the circuit board 4 having formed thereon a metal thin film (dummy pattern 2) for adjusting such residual ratio. As illustrated in FIG. 1, the circuit board 4 comprises an insulating layer 10, a wiring 6 formed on the surface of the insulating layer 8, and a metal thin film for residual ratio adjustment (dummy pattern 2, including circle patterns and pairs of right triangles in which the hypotenuses face each other).

The wiring 6 is ordinarily formed by etching a copper foil. In the explanation that follows, therefore, the wiring 6 will be formed of copper foil, and the residual ratio of the metal thin film will be called residual copper ratio.

The layer count of the circuit board 4 has increased in recent years. Specifically, the circuit board 4 comprises a plurality of insulating layers 10, and a plurality of wiring layers comprising wirings 6. In each wiring layer, the total surface area occupied by the wiring varies depending on the wiring pattern formed on the respective wiring layer. Therefore, the residual copper ratio of the wiring layer in which only the wirings 6 are formed is not fixed but depends on the wirings 6.

When the circuit board is reflow-soldered, the wiring layers 8 (for instance, copper foil) undergo a greater thermal expansion than the insulating layer (for instance, glass epoxy resin), during heating of the circuit board. As a result, the wiring layers 8 exert a tensile stress on the insulating layer that is in contact with the wiring layers 8.

FIG. 2 is a diagram for explaining a cross section of the circuit board 4, in which the circuit board comprises one insulating layer 10 and wirings 6 formed on a front face side 12 and the rear face side 14 of the insulating layer 10.

The stress exerted by the wiring layers 8 on the insulating layer 10 becomes greater as the residual copper ratio of the wiring layer 8 increases. In the above-described circuit board 4 comprising a plurality of wiring layers 8 having different residual copper ratios, therefore, the insulating layer 10 undergoes tensile stresses of dissimilar magnitude from the wiring layer 8 formed on the front face side 12 of the insulating layer 10 and from the wiring layer 8 formed on the rear face side 14. The insulating layer 10 becomes stretched on account of these tensile stresses. Since the magnitude of the tensile stress is different on the front face side and the rear face side, the insulating layer 10 warps as a result, the outward side of warped bow being herein the side where tensile stress is stronger owing to a higher residual copper ratio as shown in FIG. 3. The broken line in FIG. 3 represents the cross section of a characterizing portion of the circuit board before reflow soldering.

In addition, the insulating layer 10 may also twist when, for instance, the in-plane distribution of tensile stress across the surface of the insulating layer 10 is uneven with the difference in tensile stress between the front and the rear faces.

The wiring layers 8 contract when the circuit board 4 is cooled. However, deformation of the insulating layer 10 is irreversible, and persists even after the circuit board 4 has reverted to room temperature. As a result, warpage and twist become permanent in the circuit board 4 after reflow soldering.

The residual copper ratio on the front face side 12 and the rear face side 14 may be equalized with a view to avoiding such deformation of the circuit board 4. Doing so balances in turn the stresses acting on the front face side 12 and the rear face side 14 of the insulating layer 10, and hence the insulating layer 10 does not deform upon reflow soldering. That is, the circuit board does not deform.

The above method using dummy patterns is a method for suppressing circuit board deformation by setting a constant residual copper ratio across the wiring layers 8, to make thereby constant the stress occurring on the front face side 12 and the rear face side 14 of the insulating layer 10.

The above method using dummy patterns is effective when the frequency band at which the circuit board 4 is used is low.

When the frequencies at which the circuit board 4 is used become higher, however, there occur various problems.

The presence of the dummy pattern 2 gives rise to parasitic capacitance and/or parasitic inductance. A higher frequency band results in greater admittance, on account of parasitic capacitance, and greater impedance, on account of parasitic inductance. As a result, there arise problems such as signal leaks between wirings due to such parasitic capacitance and parasitic inductance (first problem).

In circuit boards used at high-frequency bands, moreover, a ground plane is ordinarily provided on the surface of the insulating layer that faces the motherboard. The purpose of this is not only affording smooth propagation of high-frequency signals along the transmission line formed by the wiring provided on the circuit board and by the ground plane, shielding, from the motherboard, the high-frequency signals that propagate across the circuit board, to prevent thereby induced noise in the motherboard.

When the above method for adjusting residual copper ratio using the dummy patterns 2 is applied to such boards, the shielding effect against high-frequency signals is diminished, and the functionality of the ground plane, which must be reinforced in the first place, is impaired, as explained below.

That is, using the above method in a high-frequency circuit board affects negatively both ground reinforcement and the ground plane shielding effect.

FIG. 4 is a cross-sectional diagram for explaining an instance of an electronic component module 18 mounted on a motherboard 16. The electronic component module 18 comprises a plurality of electronic components 20, and a circuit board 4 on which the electronic components 20 are mounted. The circuit board 4 comprises ordinarily a plurality of insulating layers, with a ground plane formed on a face 22 that opposes the motherboard (insulating layer surface that is closest to the motherboard 16).

The ground plane comprises ordinarily a solid pattern having no in-plane structure. The ground plane is formed so as to cover the greater part (for instance, 60% or more, preferably 70% or more, more preferably 80% or more, yet more preferably 90% or more) of the face 22 (hereinafter, opposing face) that opposes the motherboard. Wiring layers are formed on the faces of insulating layers other than the opposing face.

As described above, providing the dummy pattern 2 in a high-frequency circuit board is not preferred. Still, the dummy pattern 2 could conceivably be provided on the wiring layers with a view to preventing occurrence of warpage and twist.

Even if a dummy pattern is provided in the wiring layers, however, the residual copper ratio of the wiring layers is lower than the residual copper ratio of the ground plane used in a high-frequency wiring board, where the ground plane covers the greater part of the insulating layer surface.

In the above method using a dummy pattern, the residual copper ratio must be constant across all conductive layers, including the conductive layer in which the ground plane is formed.

To use the above method, therefore, the residual copper ratio of the ground plane must be lowered to match the residual copper ratio of the wiring layers in which the dummy pattern is provided. As a result, the surface area of the ground plane must be made smaller.

The shielding effect of the ground plane against high-frequency signals is diminished thereby, and the functionality of the ground plane, which must be reinforced in the first place, is impaired (second problem).

As illustrated in FIG. 4, moreover, the electronic components 20 are mounted only on one side of the circuit board 4 that in turn is mounted on the motherboard 16. However, wiring is concentrated on the face where the electronic components 20 are mounted, which leaves virtually no room for providing the dummy pattern 2. This makes it difficult to employ the above method of uniformizing the residual copper ratio by providing a dummy pattern (third problem).

### SUMMARY OF THE INVENTION

It is thus an object of the present invention to provide an electronic component module, and a circuit board thereof, the electronic component module comprising a circuit board (in particular, a high-frequency board) in which the shielding effect of a ground plane is not impaired and in which warpage and twist of the circuit board on account of reflow soldering is suppressed.

(First Invention)

To achieve the above-described object, a first aspect of the present invention is an electronic component module, including: a circuit board having: an insulating layer; a plurality of conductive layers formed on respective surfaces of the insulating layer; a ground plane comprising one of the conductive layers and covering the greater part of the surface; and wiring formed on another of the surfaces and comprising the conductive layer; and an electronic component mounted on the circuit board and connected by the wiring, wherein a plurality of slits, formed by removing the conductive layer, are provided in the ground plane.

In the first aspect, the stress generated by thermal expansion of the ground plane can be distributed by providing slits in the ground plane, and hence warpage and twist of the circuit board, caused by reflow soldering, can be suppressed without the shielding effect of the ground plane becoming impaired.

(Second Invention)

To achieve the above-described object, a second aspect of the present invention is an electronic component module according to the first aspect, wherein the circuit board is obtained by laminating a plurality of the insulating layers.

In the electronic component module comprising a circuit board obtained by laminating a plurality of the insulating layers, according to the second aspect, the stress generated by thermal expansion of the ground plane can be distributed by providing slits in the ground plane, and hence warpage and twist of the circuit board, caused by reflow soldering, can be suppressed without the shielding effect of the ground plane becoming impaired.

(Third Invention)

To achieve the above-described object, a third aspect of the present invention is an electronic component module according to the first aspect, wherein the slits have a plurality of extending directions.

The third aspect allows suppressing warpage in the extending directions.

(Fourth Invention)

To achieve the above-described object, a fourth aspect of the present invention is an electronic component module according to the third aspect, wherein the slits, having different extending directions, intersect each other.

In the fourth aspect, intersecting slits can be designed as on single slit pattern, which facilitates pattern design.

(Fifth Invention)

To achieve the above-described object, a fifth aspect of the present invention is an electronic component module according to the fourth aspect, wherein the extending directions are perpendicular to each other.

In the fifth aspect, a cross pattern can be designed as one single slit pattern, which makes pattern design easier.

(Sixth Invention)

To achieve the above-described object, a sixth aspect of the present invention is an electronic component according to the third aspect, wherein the shape of the circuit board is a rectangle, one of the extending directions being parallel to one side of the rectangle, and another of the extending directions being parallel to another side of the rectangle.

In the sixth aspect, the extending directions of the slits can coincide with coordinate axes (X-axis and Y-axis) in CAD (Computer-Aided Design). This makes pattern design easier as a result.

(Seventh Invention)

To achieve the above-described object, a seventh aspect of the present invention is an electronic component module according to the first aspect, wherein the slits do not reach an outer edge of the ground plane.

In the seventh aspect, the surface area that is bounded by the outer edge, i.e. by the outermost closed curve, of the ground plane does not shrink, and hence the shielding effect of the ground plane is not impaired.

(Eighth Invention)

To achieve the above-described object, an eighth aspect of the present invention is an electronic component module according to the first aspect, wherein the plurality of slits are disposed so as to intersect at least one straight line.

In the eighth aspect, the stress generated on account of expansion of the ground plane can be spread better, and hence circuit board warpage and twist can be suppressed more effectively.

(Ninth Invention)

To achieve the above-described object, a ninth aspect of the present invention is an electronic component module according to the first aspects, wherein the insulating layer includes a glass epoxy resin.

In the electronic component module comprising a circuit board in which the insulating layer comprises a glass epoxy resin, according to the ninth aspect, the stress generated by thermal expansion of the ground plane can be distributed by providing slits in the ground plane, and hence warpage and twist of the circuit board, caused by reflow soldering, can be suppressed without the shielding effect of the ground plane becoming impaired.

(Tenth Invention)

To achieve the above-described object, a tenth aspect of the present invention is a circuit board, including an insulating layer; a plurality of conductive layers formed on respective surfaces of the insulating layer; a ground plane comprising one of the conductive layers and covering the greater part of the surface; and wiring formed on another of the surfaces and comprising the conductive layer, wherein a plurality of slits, formed by removing the conductive layer, are provided in the ground plane.

In the tenth aspect, the stress generated by thermal expansion of the ground plane can be distributed by providing slits in the ground plane, and hence warpage and twist of the circuit board, caused by reflow soldering, can be suppressed without the shielding effect of the ground plane becoming impaired.

(Eleventh Invention)

To achieve the above-described object, an eleventh invention of the present invention is a circuit board according to the tenth aspect, wherein the circuit board is obtained by laminating a plurality of the insulating layer.

In the circuit board obtained by laminating a plurality of the insulating layers according to the eleventh aspect, the stress generated by thermal expansion of the ground plane can be distributed by providing slits in the ground plane, and hence warpage and twist of the circuit board, caused by reflow soldering, can be suppressed without the shielding effect of the ground plane becoming impaired.

(Twelfth Invention)

To achieve the above-described object, a twelfth aspect of the present invention is a circuit board according to the tenth aspect, wherein the slits have a plurality of extending directions.

The twelfth aspect allows suppressing warpage in the extending directions.

(Thirteenth Invention)

To achieve the above-described object, a thirteenth aspect of the present invention is a circuit board according to the twelfth aspect, wherein the slits, having different extending directions, intersect each other.

In the thirteenth aspect, intersecting slits can be designed as on single slit pattern, which facilitates pattern design.

(Fourteenth Invention)

To achieve the above-described object, a fourteenth aspect of the present invention is a circuit board according to the thirteen aspect, wherein the extending directions are perpendicular to each other.

In the fourteenth aspect, a cross pattern can be designed as one single slit pattern, which makes pattern design easier.

(Fifteenth Invention)

To achieve the above-described object, a fifteenth invention of the present invention is a circuit board according to the twelfth aspect, wherein the shape of the circuit board is a rectangle, one of the extending directions being parallel to one side of the rectangle, and another of the extending directions being parallel to another side of the rectangle.

In the fifteenth aspect, the extending directions of the slits can coincide with coordinate axes (X-axis and Y-axis) in CAD. This makes pattern design easier as a result.

(Sixteenth Invention)

To achieve the above-described object, a sixteenth aspect of the present invention is a circuit board according to the tenth aspect, wherein the slits do not reach an outer edge of the ground plane.

In the sixteenth aspect, the surface area that is bounded by the outer edge, i.e. by the outermost closed curve, of the ground plane does not shrink, and hence the shielding effect of the ground plane is not impaired.

(Seventeenth Invention)

To achieve the above-described object, a seventeenth invention of the present invention is a circuit board according to the tenth aspect of the present invention, wherein the plurality of slits are disposed so as to intersect at least one straight line.

In the seventeenth aspect, the stress generated on account of expansion of the ground plane can be spread better, and hence circuit board warpage and twist can be suppressed more effectively.

(Eighteenth Invention)

To achieve the above-described object, an eighteenth aspect of the present invention is a circuit board according to the tenth aspects, wherein the insulating layer comprises a grass epoxy resin.

In the circuit board in which the insulating layer comprises a glass epoxy resin, according to the eighteenth aspect, the stress generated by thermal expansion of the ground plane can be distributed by providing slits in the ground plane, and hence warpage and twist of the circuit board, caused by reflow soldering, can be suppressed without the shielding effect of the ground plane becoming impaired.

In the present invention, thus, the stress generated by thermal expansion of the ground plane can be distributed by providing slits in the ground plane, and hence warpage and twist of the circuit board, caused by reflow soldering, can be suppressed without the shielding effect of the ground plane becoming impaired.

Embodiments of the present invention will now be described with reference to the drawings. The embodiments are for assisting the understanding of the present invention, and not for limiting the application of the present invention to these embodiments.

### BRIEF DESCRIPTION OF THE DRAWINGS

FIG. 1 is a diagram for explaining the surface of the circuit board having formed thereon a dummy pattern 2 for uniformizing the residual ratio of a metal thin film on each surface by providing a dummy pattern.

FIG. 2 is a diagram for explaining a cross section of the circuit board, in which the circuit board comprises one insulating layer and wirings formed on a front face side and the rear face side of the insulating layer.

FIG. 3 is a diagram for explaining a cross section of warped circuit board after reflow soldering.

FIG. 4 is a cross-sectional diagram for explaining a state of an electronic component module mounted on a motherboard.

FIG. 5 is a cross-sectional diagram for explaining a state where an electronic component module according to Embodiment 1 is mounted on a motherboard.

FIG. 6 is an example of a block diagram of the electronic component module according to Embodiment 1.

FIG. 7 is a plan-view diagram for explaining the constitution of an opposing face of the circuit board according to Embodiment 1 (surface opposing the motherboard)

FIG. 8 is a cross-sectional diagram for explaining the constitution of a circuit board according to Embodiment 1.

FIG. 9 is a plan-view diagram for explaining the constitution of a wiring layer that is formed on one insulating layer making up the circuit board according to Embodiment 1, and comprises a plurality of wirings.

FIG. 10A and FIG. 10B are diagrams for explaining the state of a circuit board after reflow soldering, the circuit board comprising a insulating layer that has, on the front face thereof, a wiring layer comprising a plurality of wirings and that has, on the rear face thereof, a ground plane comprising a solid pattern.

FIG. 11A and FIG. 11B are diagrams diagram for explaining the state of the circuit board after reflow soldering, when slits are provided in the ground plane.

FIG. 12 is a plan-view diagram for explaining the constitution of the opposing face (face opposing the motherboard) of a comparative circuit board, for comparison purposes.

FIG. 13 is a diagram for explaining temperature changes in a reflow oven used for preparing the specimens in the measurement.

FIG. 14 is a diagram for explaining the results of a flatness measurement performed on the surface of the measurement circuit board after reflow soldering.

FIG. 15 is a diagram for explaining the results of a flatness measurement performed on the comparative circuit board after reflow soldering.

FIG. 16 is a plan-view diagram for explaining the constitution of an opposing face (face opposing the motherboard) of a circuit board according to Embodiment 2.

FIG. 17 is a plan-view diagram for explaining the constitution of an opposing face (face opposing the motherboard) of a circuit board according to Embodiment 3.

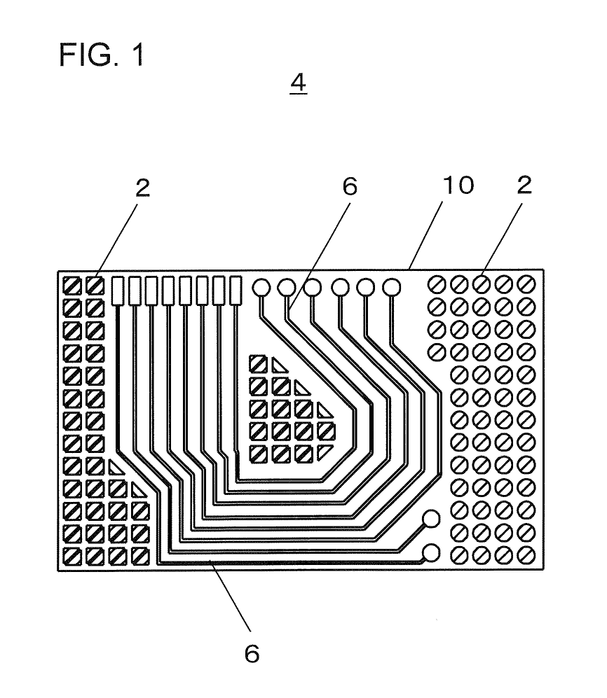

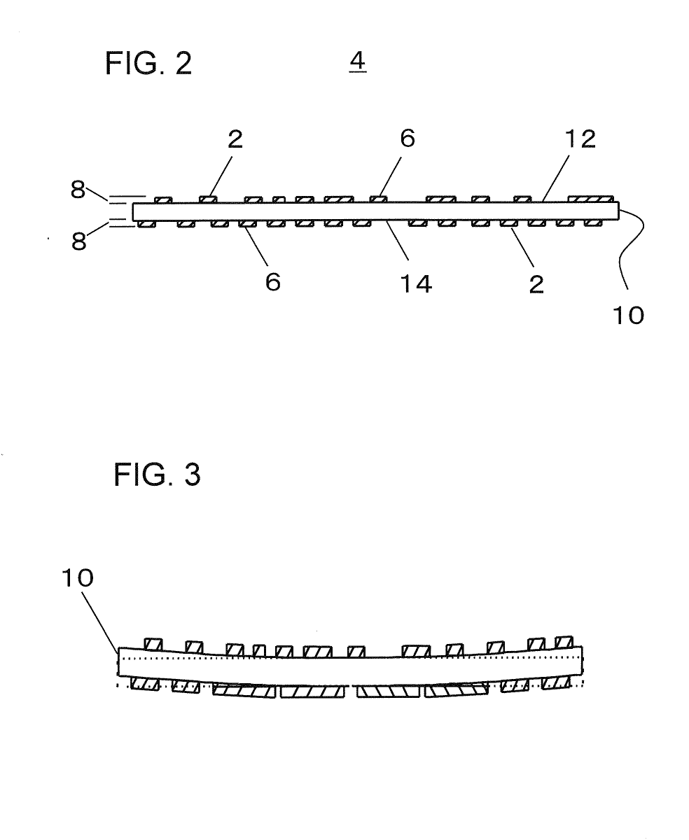

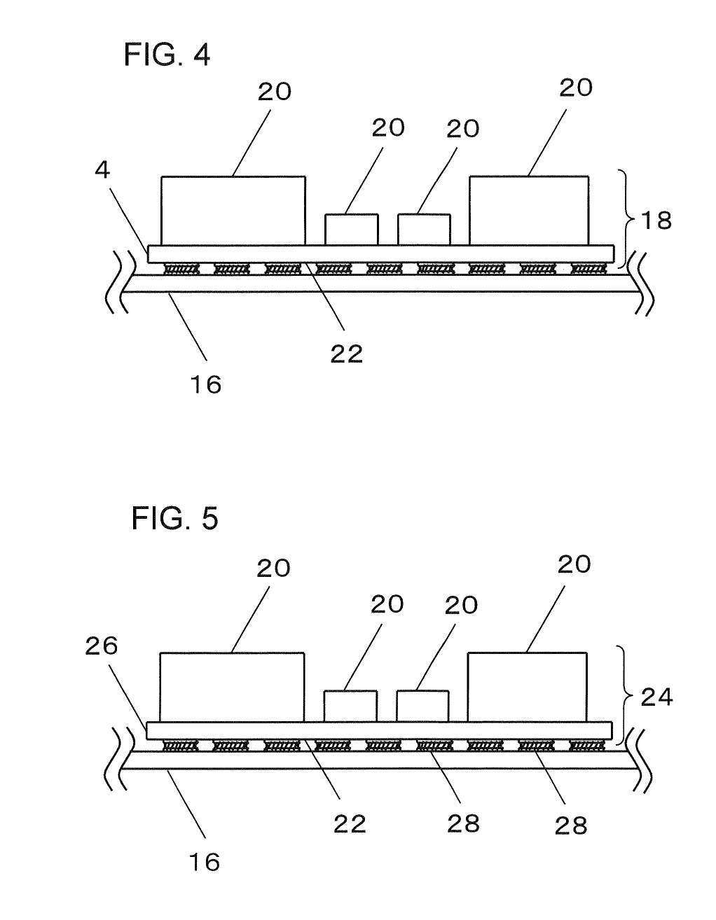

### DESCRIPTION OF THE PREFERRED EMBODIMENTS

### Embodiment 1

The present embodiment relates to an electronic component module, and a circuit board thereof, the electronic component module comprising a circuit board in which a ground plane is provided with a plurality of slits the extending directions of which are perpendicular to each other.

(1) Constitution

FIG. 5 is a cross-sectional diagram for explaining an instance where an electronic component module 24 according to the present embodiment is mounted on, for instance, a motherboard 16 of a mobile phone. The electronic component module 24 comprises a circuit board 26, and electronic components 20 such as a filter and so forth, connected among them by wiring formed in the circuit board 26.

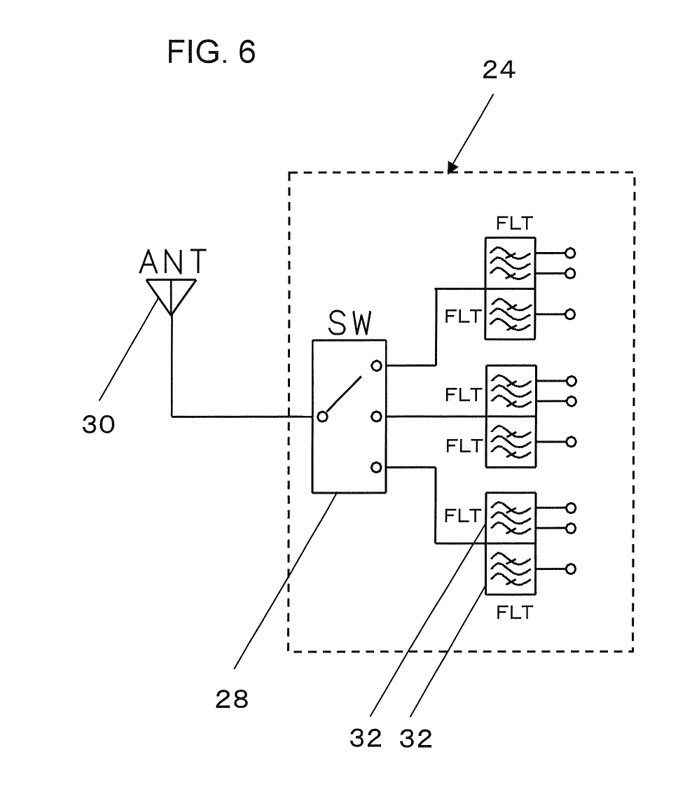

FIG. 6 is an example of a block diagram of the electronic component module 24. The electronic component module 24 comprises, for instance, an antenna switch 28 connected to an input terminal of an external antenna 30, and a plurality of filters 32 connected to an output terminal of the antenna switch 28.

The circuit board 26, having mounted thereon the electronic components 20 such as the filters 32 and so forth, is mounted in turn on the motherboard 16, by way of, for instance, solder bumps 28, as illustrated in FIG. 5.

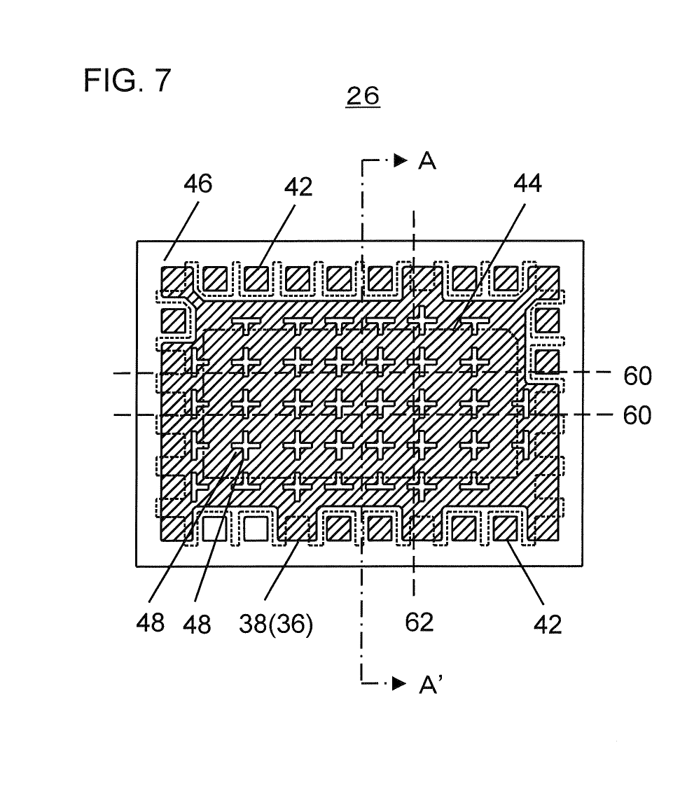

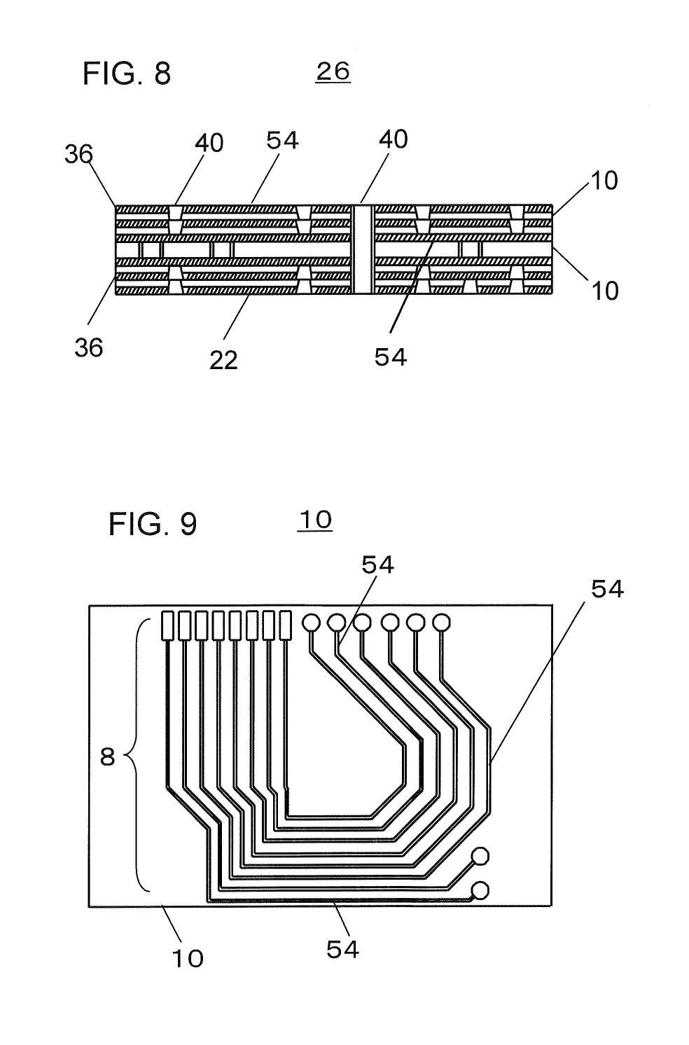

FIG. 7 is a plan-view diagram for explaining the constitution of an opposing face of the circuit board 26 (surface opposing the motherboard 16). FIG. 8 is a cross-sectional diagram of a cross section of the circuit board 26, along the line A-A′ of FIG. 7, viewed from the direction of the arrows.

As illustrated in FIG. 8, the circuit board 26 comprises a plurality of laminated insulating layers 10, and a plurality of conductive layers 36 formed on the surfaces of the insulating layers 10. The insulating layers 10 comprise a glass epoxy resin.

A ground plane 38 (FIG. 7), comprising one conductive layer 36, is formed on a face opposing the motherboard (opposing face 22), covering the greater part (for instance, 60% or more, preferably 70% or more, more preferably 80% or more, yet more preferably 90% or more) of the surface of one insulating layer 10. Around the ground plane 38 there are provided pads 42 connected to the wiring layers by way of below-described via holes 40. The pads 42 are electrically connected to wiring in the motherboard 16 by way of the solder bumps 28.

A pad region 44 (ground pad) is also provided in the ground plane 38, the pad region 44 being electrically connected to the ground of the motherboard 16 by way of the solder bumps 28. A resist 46, for preventing protrusion of the solder bumps, is provided around the ground plane 38. The resist 46 is provided between the outer edge of the circuit board 26 and the broken line illustrated in FIG. 7. The resist 46 is formed so as not to cover the surface of the pads 42.

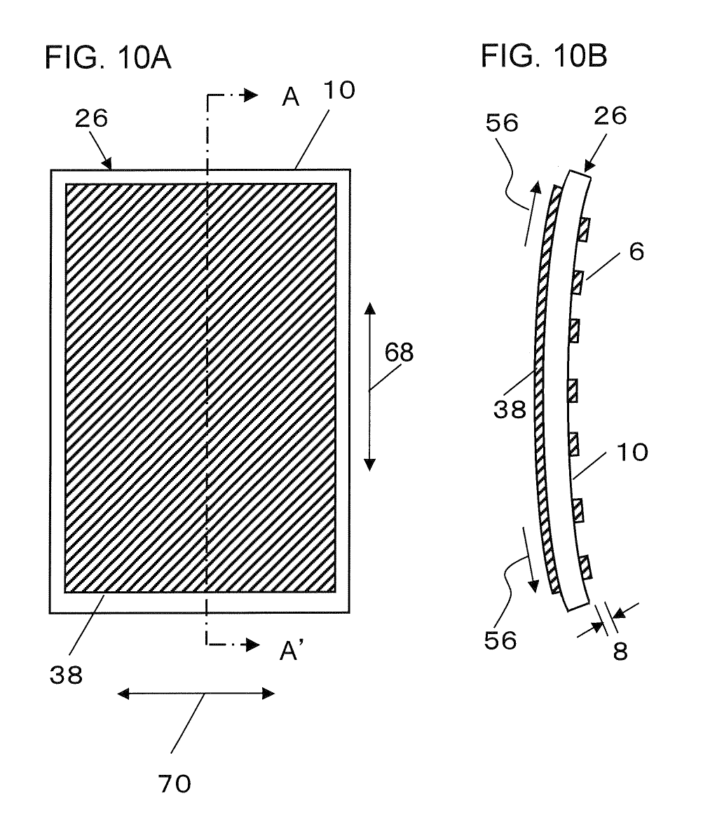

Meanwhile a wiring 54, comprising for instance one conductive layer 36, is provided on the surface of an insulating layer that is different from the surface on which the ground plane 38 is formed, as illustrated in FIG. 9. FIG. 9 is a plan-view diagram for explaining the constitution of a wiring layer 8 that is formed on one insulating layer 10 and comprises a plurality of wirings 54.

The conductive layers 36 are electrically connected by way of a metal layer that fills via holes 40 (see FIG. 8).

A plurality of slits 48, formed by removing the conductive layer 36, are provided in the ground plane 38. As discussed in the section “Rationale” below, warpage of the circuit board caused by reflow soldering can be suppressed by providing such slits.

In the example illustrated in FIG. 7, two slits 48 are paired in such a manner that the extending directions of the slits are perpendicular to each other.

In the present embodiment, thus, the slits have a plurality of (two) extending directions. When that is the case, warpage can be suppressed in the respective extending directions, as explained in the section “Rationale” below.

In the present embodiment, the slits 48, having different extending directions, intersect each other. Such intersecting slits 48 can be designed as a single slit pattern, which makes pattern design easier.

In the present embodiment, for instance, slits are perpendicular to each other. A cross pattern can thus be designed as a single slit pattern, which makes pattern design easier.

As illustrated in FIG. 7, the circuit board 26 is shaped as a rectangle. Herein, one of the extending directions of the slits 48, of which extending directions are perpendicular to each other, is parallel to one of the sides of the rectangle, while the other extending direction of the slits is parallel to the other side of the rectangle.

That way, the extending directions of the slits can coincide with coordinate axes (X-axis and Y-axis) in CAD. This makes pattern design easier as a result.

In the present embodiment illustrated in FIG. 7, the plurality of slits 48 are disposed so as to intersect at least one straight line 60, 62. That way, the stress generated on account of expansion of the ground plane 38 can be spread better, as explained in the section “Rationale” below, and hence circuit board warpage and twist can be suppressed more effectively.

As illustrated in FIG. 7, the slits 48 are provided so as not to reach the outer edge of the ground plane 38. As a result, the surface area that is bounded by the outer edge, i.e. by the outermost closed curve, of the ground plane does not shrink, and hence the shielding effect of the ground plane is not impaired.

In the above examples there are provided a plurality of insulating layers 10, but there may be provided a single insulating layer 10. That is, a wiring layer may be provided on the front face of one insulating layer 10 and the ground plane 38 may be provided on the rear face of the insulating layer 10. In other words, the circuit board may be a so-called double-sided printed board.

The ground plane 38 may be provided not on the opposing face 22 but on the other face when, for instance, induced noise in the motherboard 16 is not a problem.

Specifically, the electronic component module 24 according to the present embodiment comprises (FIG. 5) a circuit board 26 (FIG. 7 and FIG. 8) having an insulating layer 10; a plurality of conductive layers 36 formed on the surfaces of the insulating layer 10; a ground plane 38 comprising one of the conductive layer 36 and covering the greater part of one of the surfaces; and wiring 54 formed on another of the surfaces and comprising conductive layer 36. The electronic component module 24 comprises moreover electronic components 20 that are mounted on the circuit board 26 and that are connected by way of the wiring 54 (FIG. 9), wherein a plurality of slits 48 are provided in the ground plane 38 by removing the conductive layer 36 (FIG. 7).

(2) Rationale

FIG. 10A and FIG. 10B are diagrams for explaining the state of a circuit board 26 after reflow soldering, the circuit board 26 comprising a insulating layer 10 that has, on the front face thereof, a wiring layer 8 comprising a plurality of wirings 6 and that has, on the rear face thereof, a ground plane 38 comprising a solid pattern.

FIG. 10A is a diagram of the circuit board 26 viewed from the rear side thereof. FIG. 10B is cross-sectional diagram of the circuit board 26 along the line A-A′ of the left diagram, viewed from the direction of the arrows.

As FIG. 10A and FIG. 10B shows, the residual copper ratio of the ground plane 38 is higher than the residual copper ratio of the wiring layer 8. When the circuit board 26 is reflow-soldered, the ground plane 38, having expanded during the temperature rise or heating process, exerts a stress 56, greater than that of the wiring layer 8, on the insulating layer 10. The circuit board 26 warps as a result, with the inward side of the warped bow being the face at which the wiring layer 8 is provided, as illustrated on FIG. 10B.

As a result of diligent research, the inventors found that this warpage can be mitigated by providing slits 48 in the ground plane 38.

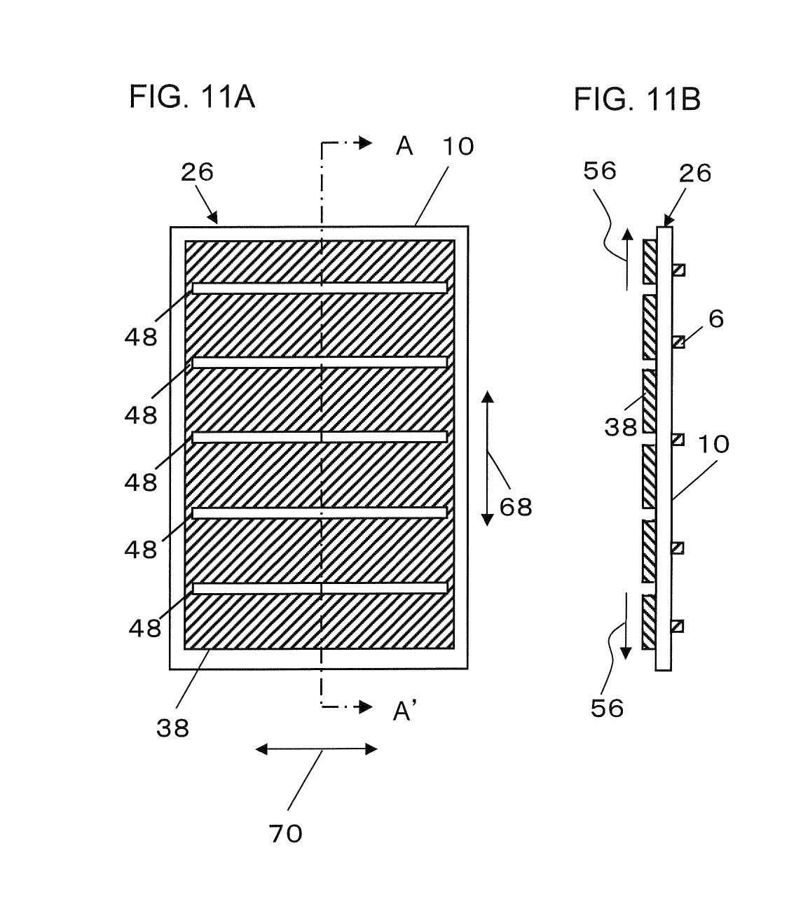

FIG. 11A and FIG. 11B are diagrams for explaining the state of the circuit board 26 after reflow soldering, when slits 48 are provided in the ground plane 38. The diagram on FIG. 11A is a diagram of the circuit board 26 viewed from the rear side thereof. The diagram on FIG. 11B is cross-sectional diagram of the circuit board 26 along the line A-A′ of the left diagram, viewed from the direction of the arrows.

As illustrated in FIG. 10A and FIG. 10B, the rectangular circuit board 26 comprising a solid-pattern ground plane 38 is subjected to large stress 56 in the long-side direction of the circuit board 26. The slits 48 are provided so as to intersect that long-side direction 68. Providing such slits 48 has the effect of mitigating the warpage of circuit board 26 caused by reflow soldering, as illustrated on FIG. 11B. Presumably, that is because small stresses develop only in the small regions into which the ground plane 38 is segmented by the slits 48. That is, stress is distributed by the slits 48, and thus warpage can be suppressed since there is not one single large stress acting on the circuit board.

Therefore, providing slits so as to intersect the direction of the stress generated by the ground plane 38 allows suppressing the warpage of the circuit board that is caused by that stress.

In the above explanation only stress in the long-side direction 68 of the circuit board 26 has been considered. In actuality, however, stress is generated also in the short-side direction 70 of the circuit board 26. Therefore, warpage in the short-side direction 70 is preferably suppressed by providing also slits that intersect the short-side direction of the circuit board 26.

(3) Characteristics

An explanation follows next on measurement results of warpage caused by reflow soldering in the circuit board 26 comprising the ground plane 38 illustrated in FIG. 7.

The circuit board 26 used for measurement (hereinafter, measurement circuit board) is a so-called 6-layer board comprising a plurality of insulating layers 10 of glass epoxy resin. A wiring layer 8 is provided on the front face of the insulating layers 10. On the rear face of the insulating layer 10 there is provided a ground plane 38 and so forth, to yield the structure illustrated in FIG. 7. The long side of the circuit board 26 measures about 8.6 mm. The short side of the circuit board 26 measures about 6.2 mm. The total thickness of the board is 400 μm.

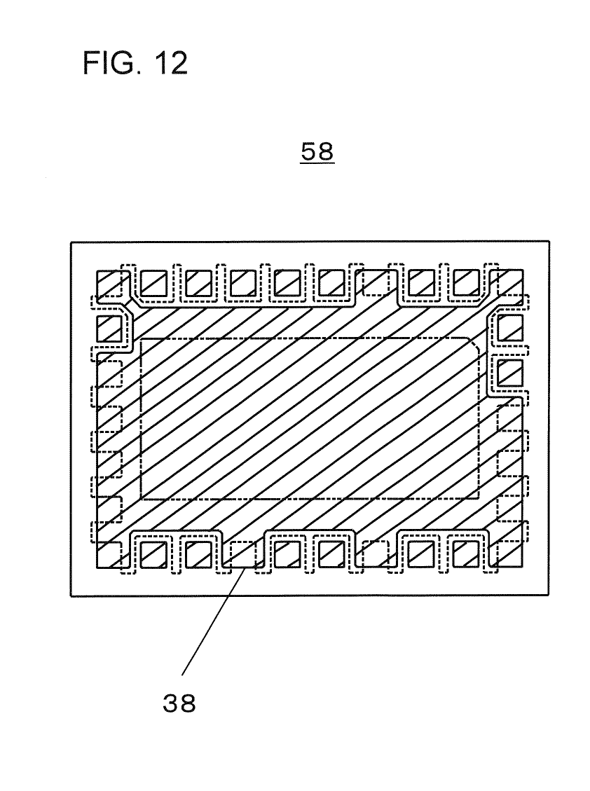

FIG. 12 is a plan-view diagram for explaining the constitution of the opposing face (face opposing the motherboard) of a circuit board (comparative circuit board 58), for comparison purposes, used for verifying the warpage-suppressing effect of the slits 48. Except for lacking slits 48 provided in the ground plane 38, the constitution of the comparative circuit board 58 is identical to that of the measurement circuit board illustrated in FIG. 7.

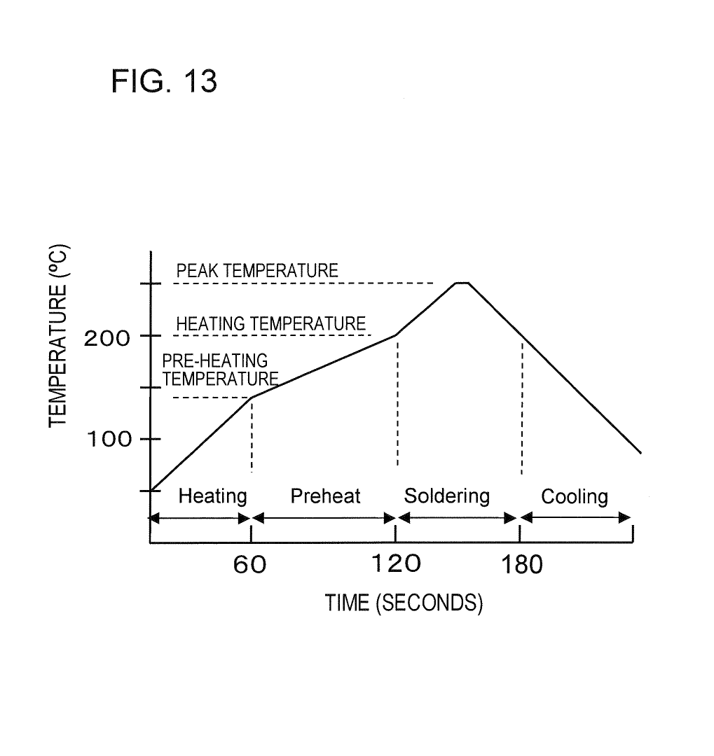

FIG. 13 is a diagram for explaining temperature changes in a reflow oven used for preparing the specimens in the present measurement. The Y-axis represents temperature and the X-axis represents time. Specifically, a circuit board having a ground plane such as that of FIG. 7 or FIG. 12 was subjected to a temperature profile, such as the one illustrated in FIG. 13, using the above reflow oven.

In the present measurement, reflow soldering involves firstly rapid heating of the circuit board to about 140° C., (temperature rise; heating) as illustrated in FIG. 13. Next, the temperature is raised gradually to 200° C., over a predetermined lapse of time, during which the circuit board is preheated (preheating). The cream solder in reflow soldering fuses at a temperature of, for instance, 200° C., depending on the characteristics of the cream solder used. Heating proceeds then up to 250° C., whereafter the temperature starts to be lowered down to 200° C. (heating; soldering). Lastly, the temperature is lowered to room temperature (temperature lowering; cooling).

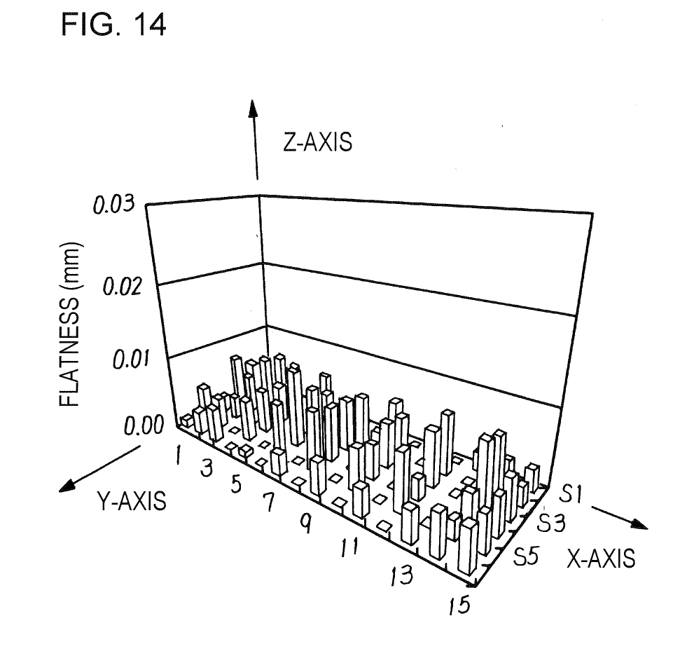

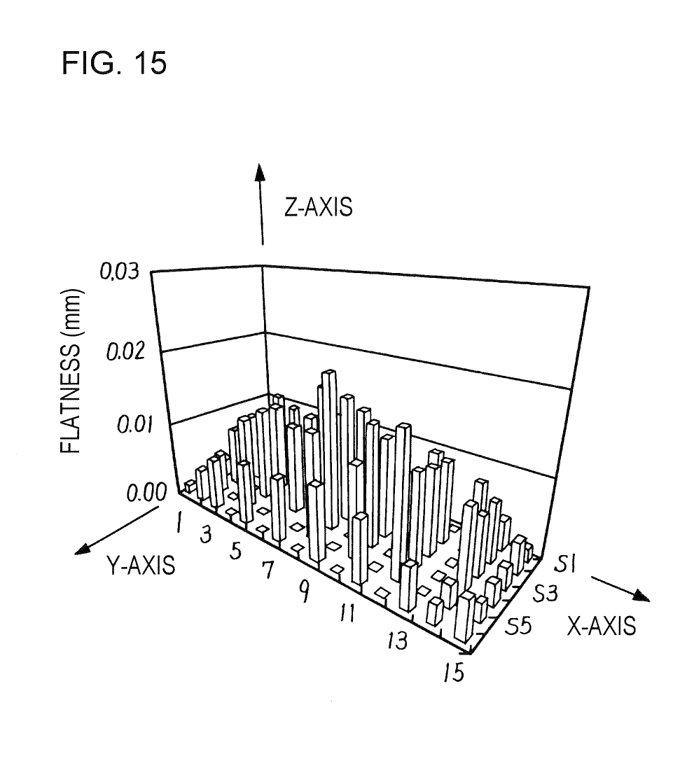

FIG. 14 is a diagram for explaining the results of a flatness measurement performed on the surface of the measurement circuit board after reflow soldering. The vertical axis (Z-axis) represents the displacement (hereinafter referred to as flatness) of the surface of the circuit board after reflow soldering, taking as a reference the surface of the warpage-free circuit board before reflow soldering. The displacement has a positive sign when warpage occurs, with the wiring layer side on the inward side of the warped bow. The XY plane represents surface positions on the circuit board.

The reference numerals (S1, S3, S5) on the Y-axis correspond to positions along the short side of the circuit board at which the short side is divided into 6 equal portions. The reference numerals (1 through 15) on the X-axis correspond to positions along the long side of the circuit board at which the long side is divided into 15 equal portions.

As illustrated in FIG. 14, flatness after reflow soldering, i.e. the displacement of the circuit board surface (front face) is no greater than 0.01 mm. When the circuit board becomes warped, displacement increases in the central portion of the circuit board. This displacement, characteristic of warpage, is not seen in FIG. 14, where small displacements are observed across the entire circuit board. The results illustrated in FIG. 14, therefore, show that circuit board warpage caused by reflow soldering can be suppressed by using a ground plane such as the one illustrated in FIG. 7. In addition, no displacement patterns, which are characteristic of twist, are observed in FIG. 14.

FIG. 15 is a diagram for explaining the results of a flatness measurement performed on the surface of the comparative circuit board after reflow soldering. The vertical axis (Z-axis), the X-axis and the Y-axis represent the same variables as those of FIG. 14.

As illustrated in FIG. 15, the surface (front face) of the comparative circuit board after reflow soldering exhibits substantial displacement in the central portion of the circuit board, reaching, at its maximum, a displacement of about 0.02 mm. The results of FIG. 15 indicate that a conventional circuit board (comparative circuit board), lacking slits in the ground plane, exhibit substantial warpage caused by reflow soldering.

That is, the results of FIG. 14 and FIG. 15 show that providing slits in the ground plane 38 allows suppressing warpage caused by reflow soldering in a high-frequency circuit board.

Meanwhile, the surface area of the slits 48 themselves is small, and hence the shielding effect of the ground plane 38 is not substantially impaired even when the slits 48 are provided in the ground plane 38. In the present embodiment, moreover, the slits 48 do not reach the outer edge of the ground plane 38. As a result, the surface area bounded by the outermost closed curve along this outer edge is not reduced. Therefore, the electromagnetic field emitted by the circuit board can be effectively shielded by currents induced along this outermost closed curve.

The present embodiment, therefore, succeeds in providing an electronic component module, and a circuit board thereof, the electronic component module comprising a circuit board (in particular, a high-frequency board) in which the shielding effect of a ground plane is not impaired and in which warpage and twist of the circuit board on account of reflow soldering is suppressed.

(4) Improvement of Moisture Sensitivity Level (MSL)

In addition to the above-described effect of suppressing warpage, the circuit board of the present embodiment affords also the effect of improving the moisture sensitivity level (hereinafter, MSL for short).

When the circuit board is left to stand in ambient air, the insulating layers 10 of glass epoxy resin or the like absorb moisture. In a circuit board 26 comprising insulating layers 10 having thus moisture absorbed therein, temperature rise or heating during reflow soldering of the circuit board 26 causes the insulating layers 10 to abruptly release the absorbed moisture.

The conductive layer that makes up the ground plane 38 comprises a metal thin film such as copper foil or the like. The ground plane 38, therefore, obstructs the above release of moisture. When, in particular, the ground plane 38 is a solid pattern, as in conventional circuit boards, this moisture has no way through which it can escape. Therefore, when such a circuit board is reflow-soldered, being heated at 200° C. or above, the expanded moisture exerts a pressure that may end up destroying the circuit board.

To avoid such an occurrence, the circuit board is ordinarily controlled by being kept in a dry atmosphere of dry nitrogen or the like, to prevent moisture absorption. That way, the circuit board does not break as a result of the thermal expansion of absorbed moisture.

Alternatively, to control a circuit board that is stored in ambient air, the moisture absorbed in the board is measured and there is determined an index, i.e. the MSL, on the basis of which the board is to be reflow-soldered within a given number of days. Breakage of the circuit board can be prevented then by carrying out reflow soldering within the period indicated by the MSL.

In the circuit board according to the present embodiment, the ground plane 38 is provided with the slits 48. As a result, the moisture that expands in the temperature rise or heating process during reflow soldering can escape into the atmosphere via these slits 48. The circuit board of the present embodiment, therefore, improves MSL. For instance, MSL can be made into a free class such that the reflow soldering can be carried out over an indefinite period of time.

### Embodiment 2

The present embodiment relates to an electronic component module, and a circuit board thereof, the electronic component module comprising a circuit board in which a ground plane is provided with a plurality of slits having different extending directions, but without the slits intersecting each other.

Except for the configuration and arrangement of the slits 48 provided in the ground plane 38 of the circuit board, the electronic component module and the circuit board thereof according to the present embodiment is identical to the electronic component module and circuit board thereof of Embodiment 1.

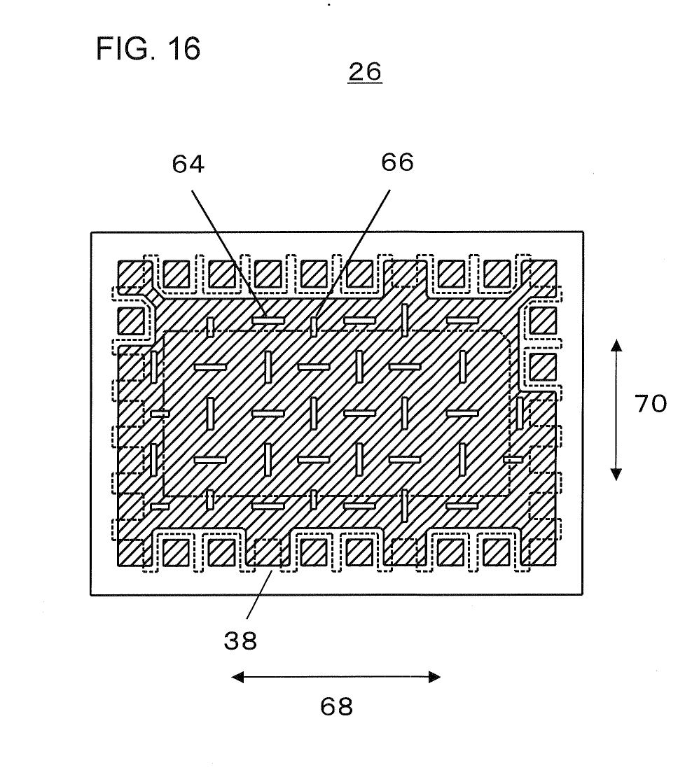

FIG. 16 is a plan-view diagram for explaining the constitution of an opposing face (face opposing the motherboard) of a circuit board 26 according to the present embodiment.

In the present embodiment, a plurality of first slits 64, parallel to a long-side direction 68 of the circuit board 26, and a plurality of second slits 66, parallel to a short-side direction 70 of the circuit board 26, are disposed alternately in the ground plane 38, as illustrated in FIG. 16.

The electronic component module and circuit board thereof according to the present embodiment afford substantially the same effect as the electronic component module and circuit board thereof according to Embodiment 1 above.

Providing in the ground plane 38 the same number of slits as in the circuit board of Embodiment 1, however, requires a more laborious design of the photomask pattern that is necessary, for instance, for a photolithographic step in which copper foils are processed and the ground plane 38 and so forth are formed.

### Embodiment 3

The present embodiment relates to an electronic component module and a circuit board thereof, comprising a circuit board in which a ground plane is provided with a plurality of slits of which extending direction is one direction only.

Except for the configuration and arrangement of the slits 48 provided in the ground plane 38 of the circuit board, the electronic component module and the circuit board thereof according to the present embodiment is identical to the electronic component module and circuit board thereof of Embodiment 2.

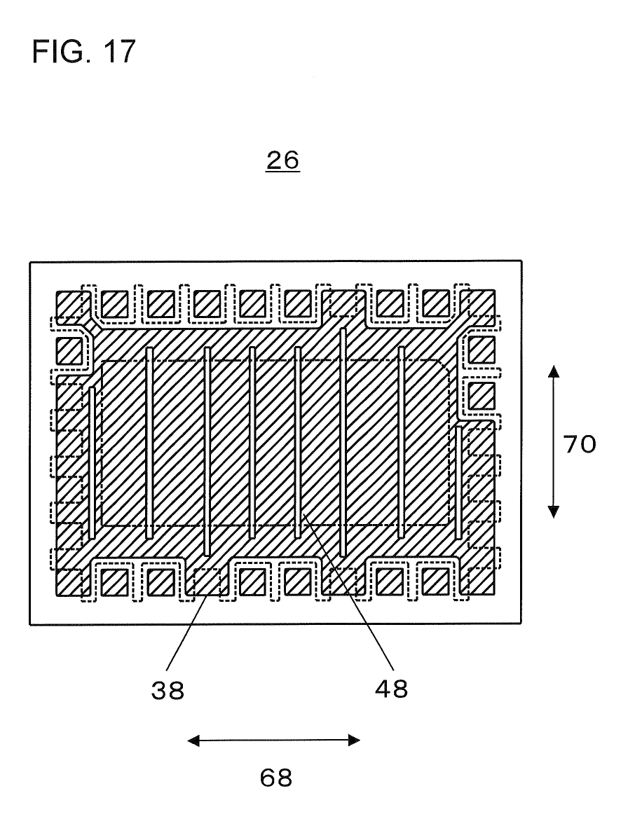

FIG. 17 is a plan-view diagram for explaining the constitution of an opposing face (face opposing the motherboard) of a circuit board 26 according to the present embodiment.

In the present embodiment, only a plurality of slits 48 parallel to a short-side direction 70 of the circuit board 26 are disposed in the ground plane 38, as illustrated in FIG. 17.

The electronic component module and circuit board thereof according to the present embodiment affords substantially the same effect as the electronic component module and circuit board thereof according to Embodiment 2 above.

In the electronic component module and circuit board thereof according to the present embodiment, however, there are provided no slits parallel to the long-side direction of the circuit board 26, and hence warpage in the short-side direction cannot be suppressed.

In the above examples, the extending direction of the slits is either the long-side direction or the short-side direction of the circuit board. The extending direction of the slits, however, is not limited to these directions. For instance, the extending direction of the slits may be parallel to the diagonals of the circuit board.

In the above examples, also, the angle with which silts having dissimilar extending directions intersect each other is a right angle. The angle with which the slits intersect one straight line, however, is not necessarily limited to a right angle, and may be, for instance, a 45° angle.

In the above examples, moreover, the slits are disposed so as to be perpendicular to one straight line. The intersection angle, however, is not necessarily limited to a right angle, and may be, for instance, a 45° angle.

What is claimed is:

1. An electronic component module, comprising:
a circuit board having: an insulating layer; a plurality of conductive layers formed on respective surfaces of the insulating layer; a ground plane comprising one of the conductive layers and covering the greater part of the surface; and wiring formed on another of the surfaces and comprising the conductive layer; and
an electronic component mounted on the circuit board and connected by the wiring,
wherein a plurality of slits, formed by removing the conductive layer, are provided in the ground plane.

2. The electronic component module according to claim 1,
wherein the circuit board is obtained by laminating a plurality of the insulating layers.

3. The electronic component module according to claim 1,
wherein the slits have a plurality of extending directions.

4. The electronic component module according to claim 3,
wherein the slits, having different extending directions, intersect each other.

5. The electronic component module according to claim 4,
wherein the extending directions are perpendicular to each other.

6. The electronic component module according to claim 3,
wherein the shape of the circuit board is a rectangle,
one of the extending directions being parallel to one side of the rectangle,
and another of the extending directions being parallel to another side of the rectangle.

7. The electronic component module according to claim 1,
wherein the slits do not reach an outer edge of the ground plane.

8. The electronic component module according to claim 1,
wherein the plurality of slits are disposed so as to intersect at least one straight line.

9. The electronic component module according to claim 1,
wherein the insulating layer comprises a glass epoxy resin.

10. A circuit board, comprising:
an insulating layer;
a plurality of conductive layers formed on respective surfaces of the insulating layer;
a ground plane comprising one of the conductive layers and covering the greater part of the surface;
and wiring formed on another of the surfaces and comprising the conductive layer,
wherein a plurality of slits, formed by removing the conductive layer, are provided in the ground plane.

11. The circuit board according to claim 10,
wherein the circuit board is obtained by laminating a plurality of the insulating layers.

12. The circuit board according to claim 10,
wherein the slits have a plurality of extending directions.

13. The circuit board according to claim 12,
wherein the slits, having different extending directions, intersect each other.

14. The circuit board according to claim 13,
wherein the extending directions are perpendicular to each other.

15. The circuit board according to claim 12,
wherein the shape of the circuit board is a rectangle,
one of the extending directions being parallel to one side of the rectangle,
and another of the extending directions being parallel to another side of the rectangle.

16. The circuit board according to claim 10,
wherein the slits do not reach an outer edge of the ground plane.

17. The circuit board according to claim 10,
wherein the plurality of slits are disposed so as to intersect at least one straight line.

18. The circuit board according to any one of claim 10,
wherein the insulating layer comprises a glass epoxy resin.
